(19) United States
(12) Patent Application Publication
(10) Pub. No.: US 2024/0030190 A1
(43) Pub. Date: Jan. 25, 2024

(54) SEMICONDUCTOR STACK STRUCTURE

(71) Applicant: CHANGXIN MEMORY TECHNOLOGIES, INC., Hefei City (CN)

(72) Inventor: Honglong SHI, Hefei City (CN)

(73) Assignee: CHANGXIN MEMORY TECHNOLOGIES, INC., Hefei City (CN)

(21) Appl. No.: 18/449,394

(22) Filed: Aug. 14, 2023

Related U.S. Application Data
(63) Continuation of application No. PCT/CN2022/127753, filed on Oct. 26, 2022.

(30) Foreign Application Priority Data
Jul. 22, 2022 (CN) 202210868614.6

(51) Int. Cl. H01L 25/065; H01L 23/00

(52) U.S. Cl. CPC H01L 25/0657; H01L 24/48; H01L 24/49; H01L 24/32; H01L 2224/48105; H01L 2224/48227; H01L 2224/4903; H01L 2224/49105; H01L 2224/32225; H01L 2224/32145; H01L 2225/0651; H01L 2225/06562; H01L 2225/06565; H01L 2224/49174; H01L 2924/3861

(57) ABSTRACT

A semiconductor stack structure at least includes: a substrate; connection pads located on a surface of the substrate; and a plurality of semiconductor dies located on the surface of the substrate and stacked in sequence in a first direction, the first direction being a thickness direction of the substrate. Each two adjacent semiconductor dies located in a same signal channel are connected to a same connection pad, and two semiconductor dies connected to a same connection pad are respectively located in a first channel region and a second channel region of a signal channel.

### CROSS-REFERENCE TO RELATED APPLICATIONS

This is a continuation of International Application No. PCT/CN2022/127753 filed on Oct. 26, 2022, which claims priority to Chinese Patent Application No. 202210868614.6 filed on Jul. 22, 2022. The disclosures of the above-referenced applications are hereby incorporated by reference in their entirety.

### BACKGROUND

A stack structure in some implementations includes a plurality of dies, and each die in the stack structure is electrically connected to the substrate. A signal channel usually connects a plurality of ranks, and dies connected to different ranks and transmitting the same signals are usually connected to a same gold finger. For example, die 1 and die 2 are connected to a same gold finger, and die 1 and die 2 are connected to Rank0 and Rank1, respectively. The gold wire connected to Rank0 and the gold wire connected to Rank1 are two parallel circuits. When Rank0 is accessed, the on-die termination (ODT) of Rank0 is turned on, which ODT can counteract most of the reflection of Rank0. At this time, because Rank1 is not accessed, the ODT of Rank1 is not turned on, and so cannot counteract the reflection effect of Rank1. As a result, the reflection of Rank1 will return to the arterial road, thus affecting Rank0. Therefore, in some implementations, when the length difference between the gold wires connected with different ranks connected with a same signal is great, it can cause a large signal reflection, which will lead to a poor performance of a semiconductor stack structure packaging substrate.

### SUMMARY

Embodiments of the disclosure relate to, but are not limited to, a semiconductor stack structure.

Embodiments of the disclosure provide a semiconductor stack structure, which at least includes: a substrate; connection pads; and a plurality of semiconductor dies.

The connection pads are located on a surface of the substrate.

The plurality of semiconductor dies are located on the surface of the substrate and are stacked in sequence in a first direction, the first direction being a thickness direction of the substrate.

Each two adjacent semiconductor dies located in a same signal channel are connected to a same connection pad, and two semiconductor dies connected to a same connection pad are respectively located in a first channel region and a second channel region of a signal channel.

### BRIEF DESCRIPTION OF THE DRAWINGS

In the accompanying drawings (which are not necessarily drawn to scale), similar reference numerals may describe similar parts in different views. Similar reference numerals with different letter suffixes may represent different examples of similar parts. The various embodiments discussed herein are generally shown in the accompanying drawings by way of example, but not limitation.

FIG. 1 is a schematic structural diagram of a semiconductor stack structure according to some embodiments of the present disclosure;

FIG. 2 is another schematic structural diagram of a semiconductor stack structure according to some embodiments of the present disclosure;

FIG. 3 is a schematic top view of a first channel region and connection pads according to some embodiments of the present disclosure;

FIG. 4 is another schematic structural diagram of a semiconductor stack structure according to some embodiments of the present disclosure;

FIG. 5 is a schematic signal transmission diagram of dies connected to a same connection pad according to some embodiments of the present disclosure;

FIG. 6 is a curve of a signal eye diagram result during a writing process of a semiconductor stack structure according to some embodiments of the present disclosure; and

FIG. 7 is a curve of a signal eye diagram result during a reading process of a semiconductor stack structure according to some embodiments of the present disclosure.

### DETAILED DESCRIPTION

Exemplary implementations of the disclosure will be described in more detail below with reference to the accompanying drawings. Although the exemplary implementations of the disclosure are shown in the accompanying drawings, it should be understood that the disclosure can be implemented in various forms and should not be limited by the specific implementations set forth herein. In contrast, these implementations are provided to enable a more thorough understanding of the disclosure and a full conveying of the scope of the disclosure to a person skilled in the art.

In the following description, numerous details are given in order to provide a more thorough understanding of the disclosure. However, it is apparent to a person skilled in the art that the disclosure can be implemented without one or more of these details. In other examples, in order to avoid confusion with the disclosure, some technical features well-known in the art are not described. That is, not all features of actual embodiments are described herein, and well-known functions and constructions are not described in detail.

In the accompanying drawings, the dimensions of a layer, a region, an element or their relative dimensions may be magnified for clarity. The same reference numeral indicates the same element throughout.

It should be understood that when an element or a layer is referred to as being “on . . . ”, “adjacent to . . . ”, “connected to . . . ” or “coupled to . . . ” another element or layer, it may be directly on, adjacent to, connected to or coupled to the another element or layer, or an intermediate element or layer may be present. In contrast, when an element is referred to as being “directly on . . . ”, “directly adjacent to . . . ”, “directly connected to . . . ” or “directly coupled to . . . ” another element or layer, the intermediate element or layer is not present. It should be understood that although the terms first, second, third and the like may be used to describe various elements, components, regions, layers and/or sections, these elements, components, regions, layers and/or sections should not be limited by these terms. These terms are only used to distinguish one element, component, region, layer or section from another element, component, region, layer or section. Therefore, without departing from the teaching of the disclosure, a first element, component, region, layer or section discussed below may be represented as a second element, component, region, layer or section. While the second element, component, region, layer or section is discussed, it does not mean that the first element, component, region, layer or section is necessarily present in the disclosure.

The terms used herein are only intended to describe the specific embodiments and are not limitations to the disclosure. As used herein, singular forms “a”, “an” and “said/the” are also intended to include plural forms, unless otherwise clearly indicated in the context. It should also be understood that the terms “consisting” and/or “including”, when used in the description, determine the presence of the described features, integers, steps, operations, elements and/or components, but do not exclude the presence or addition of one or more other features, integers, steps, operations, elements, components, and/or groups. As used herein, the term “and/or” includes any and all combinations of related items listed.

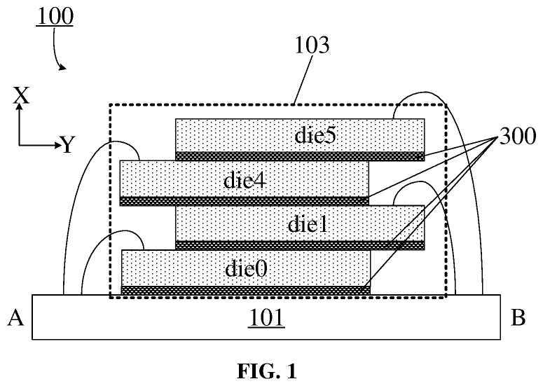

Embodiments of the disclosure provide a semiconductor stack structure. FIG. 1 is a schematic structural diagram of a semiconductor stack structure according to some embodiments of the present disclosure. As shown in FIG. 1, a semiconductor stack structure 100 includes: a substrate 101; connection pads (not shown in FIG. 1) located on a surface of the substrate 101; and a plurality of semiconductor dies 103 located on the surface of the substrate 101 and stacked in sequence in a first direction.

In some embodiments, the connection pads located on the surface of the substrate may be gold fingers.

In the embodiments of the disclosure, the thickness direction of the substrate is defined as the first direction, and any direction in a plane where the substrate is located is defined as a second direction. The first direction is perpendicular to the second direction. For example, the first direction may be the X-axis direction in FIG. 1, and the second direction may be the Y-axis direction in FIG. 1. The plurality of semiconductor dies 103 stacked in sequence in the X-axis direction include die0, die 1, die4 and die5.

In the embodiments of the disclosure, each two adjacent semiconductor dies located in a same signal channel are connected to a same connection pad, and two semiconductor dies connected to a same connection pad are respectively located in a first channel region and a second channel region of a signal channel. Still referring to FIG. 1, in the embodiments of the disclosure, the signal channels include a first signal channel A and a second signal channel B.

Still referring to FIG. 1, the semiconductor dies die0 and die4 are located in the first signal channel A, and die1 and die5 are located in the second signal channel B. The two adjacent semiconductor dies die0 and die4 located in the first signal channel A are connected to a same connection pad, and the two adjacent semiconductor dies die1 and die5 located in the second signal channel B are connected to a same connection pad.

It is to be noted that, as seen from FIG. 1, die0 and die1, die1 and die4, and die4 and die5 are two dies adjacent in position, respectively, but die0 and die4 are located in the first signal channel A, and die1 and die5 are located in the second signal channel B. Die0 and die1, die1 and die4, die4 and die5 are located in different signal channels, respectively, therefore, die0 and die4 are two adjacent semiconductor dies located in the first signal channel A, and die1 and die5 are two adjacent semiconductor dies located in the second signal channel B.

In the embodiments of the disclosure, the semiconductor dies die0 and die4 connected to the same connection pad are located in a first channel region and a second channel region of the first signal channel A, respectively. The semiconductor dies die1 and die5 connected to the same connection pad are located in a first channel region and a second channel region of the second signal channel B, respectively. In some embodiments, a first channel region may be a Rank0 region, and a second channel region may be a Rank1 region.

In some embodiments, still referring to FIG. 1, the semiconductor stack structure 100 further includes an isolation attach film 300 located between two adjacent semiconductor dies. The isolation attach film 300 is located on a side of a semiconductor die close to the substrate 101 in the X-axis direction. The isolation attach film 300 may be a die attach film (DAF) or a film over wire (FOW). In some embodiments, the die attach film may further include a first attach film and a second attach film. The second attach film is on the first attach film, and the elasticity modulus of the first attach film is greater than that of the second attach film. The first attach film is in contact with a front surface (an active surface) of the semiconductor die, and the second attach film is in contact with a back surface of the semiconductor die. The heat generated from the front surface of the semiconductor die is greater than the heat generated from the back surface of the semiconductor die, and warping of the semiconductor die can be improved since the elastic modulus of the first attach film is greater.

In the embodiments of the disclosure, each two adjacent semiconductor dies located in a same signal channel are connected to a same connection pad, and two semiconductor dies connected to a same connection pad are respectively located in a first channel region and a second channel region of a signal channel. That is, in the embodiments of the disclosure, two semiconductor dies which are located in the different channel regions of a same signal channel and are connected with a same signal are arranged adjacently, so that the length difference between gold wires connected to the two semiconductor dies is reduced, and further the signal reflection is reduced, thus improving the performance of a semiconductor stack structure packaging substrate.

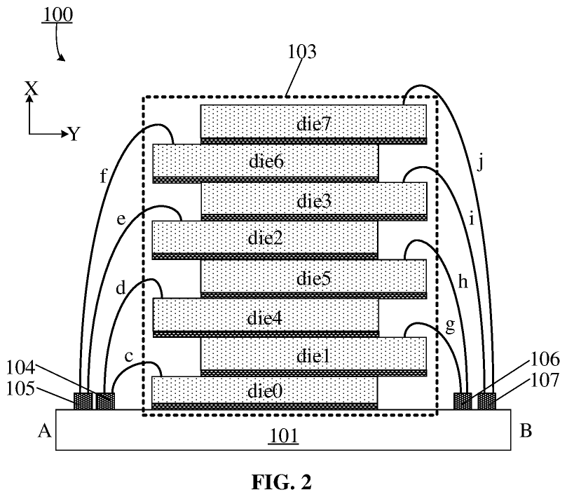

FIG. 2 is another schematic structural diagram of a semiconductor stack structure according to some embodiments of the present disclosure. As shown in FIG. 2, a semiconductor stack structure 100 includes: a substrate 101; connection pads located on a surface of the substrate 101; and a plurality of semiconductor dies 103 located on the surface of the substrate 101 and stacked in sequence in the X-axis direction. The plurality of semiconductor dies 103 include die0, die1, die4, die5, die2, die3, die6, and die7.

In the embodiments of the disclosure, each two adjacent semiconductor dies located in a same signal channel are connected to a same connection pad, and two semiconductor dies connected to a same connection pad are respectively located in a first channel region and a second channel region of a signal channel.

Still referring to FIG. 2, in embodiments of the disclosure, the connection pads include a first connection pad 104, a second connection pad 105, a third connection pad 106, and a fourth connection pad 107; and the signal channels include a first signal channel A and a second signal channel B. Each two adjacent semiconductor dies in sequence located in the first signal channel A are respectively connected to the first connection pad 104 and the second connection pad 105; and each two adjacent semiconductor dies in sequence located in the second signal channel B are respectively connected to the third connection pad 106 and the fourth connection pad 107.

Still referring to FIG. 2, the semiconductor dies die0, die4, die2 and die6 are all located in the first signal channel A; and die1, die5, die3 and die7 are all located in the second signal channel B. Each two adjacent semiconductor dies located in the first signal channel A include die0 and die4, and die2 and die6, so that die0 and die4 are connected to the same connection pad 104, and die2 and die6 are connected to the same connection pad 105. Each two adjacent semiconductor dies located in the first signal channel B include die1 and die5, and die3 and die7, so that die1 and die5 are connected to the same connection pad 106, and die3 and die7 are connected to the same connection pad 107.

It is to be noted that in the embodiments of the disclosure, a positional distribution of the connection pad 104 and the connection pad 105, and the connection pad 106 and the connection pad 107 on the substrate is not limited to the relationship shown in FIG. 2. Only one possible positional distribution relationship is shown in FIG. 2 for ease of understanding.

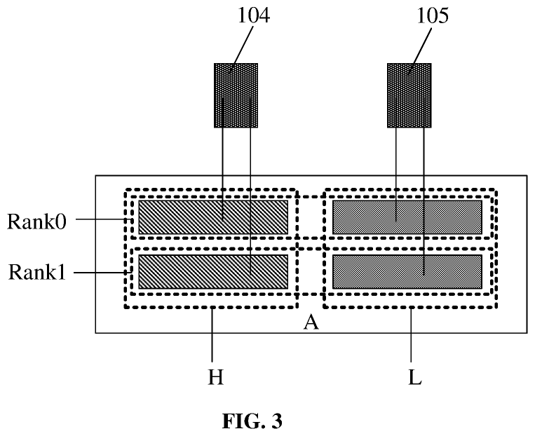

FIG. 3 is a top view of a first channel region and connection pads according to some embodiments of the present disclosure. As shown in FIG. 3, a first signal channel A includes two different channel regions, which are a first channel region (Rank0 region) and a second channel region (Rank1 region), respectively. Each rank region can be divided into a high signal region H (Byte1), e.g. DQ8-15, and a low signal region L (Byte0), e.g. DQ0-7, according to different transmission signals. Dies connected via a same connection pad can transmit a same signal. Accordingly, the high signal region H of the Rank0 region and that of the Rank1 region are both connected to the connection pad 104, and the low signal region L of the Rank0 region and that of the Rank1 region are both connected to the connection pad 105.

In some embodiments, still referring to FIG. 2 and FIG. 3, the two semiconductor dies die0 and die4 connected to the connection pad 104 are located in the Rank0 region and the Rank1 region of the first signal channel A, respectively. The two semiconductor dies die2 and die6 connected to the connection pad 105 are located in the Rank0 region and the Rank1 region of the first signal channel A, respectively. The two semiconductor dies die1 and die5 connected to the connection pad 106 are located in a first channel region (i.e. a Rank0 region) and a second channel region (i.e. a Rank1 region) of the second signal channel B, respectively. The two semiconductor dies die3 and die7 connected to the connection pad 107 are located in the Rank0 region and the Rank1 region of the second signal channel B, respectively.

In some embodiments, the semiconductor stack structure 100 further includes connection structures. The connection structures are used for connecting the semiconductor dies to the connection pads.

In some embodiments, the connection structures include at least first connection structures and second connection structures. The first connection structures are used for connecting two adjacent semiconductor dies located in the first signal channel A to the first connection pad 104. The second connection structures are used for connecting another two adjacent semiconductor dies located in the first signal channel A to the second connection pad 105.

In some embodiments, still referring to FIG. 2, the first connection structures include a first sub-connection structure c and a second sub-connection structure d. The first sub-connection structure c is used for connecting the semiconductor die die0 located in the first signal channel A and in the Rank0 region thereof to the first connection pad 104; and the second sub-connection structure d is used for connecting the semiconductor die die4 located in the first signal channel A and in the Rank 1 region thereof to the first connection pad 104.

In some embodiments, still referring to FIG. 2, the second connection structures include a third sub-connection structure e and a fourth sub-connection structure f. The third sub-connection structure e is used for connecting the semiconductor die die2 located in the first signal channel A and in the Rank0 region thereof to the second connection pad 105, and the fourth sub-connection structure f is used for connecting the semiconductor die die6 located in the first signal channel A and in the Rank 1 region thereof to the second connection pad 105.

In some embodiments, the connection structures further include third connection structures and fourth connection structures. The third connection structures are used for connecting two adjacent semiconductor dies located in the second signal channel B to the third connection pad 106. The fourth connection structures are used for connecting another two adjacent semiconductor dies located in the second signal channel B to the fourth connection pad 107.

In some embodiments, still referring to FIG. 2, the third connection structures include a fifth sub-connection structure g and a sixth sub-connection structure h. The fifth sub-connection structure g is used for connecting the semiconductor die die1 located in the second signal channel B and in the Rank0 region thereof to the third connection pad 106; and the sixth sub-connection structure h is used for connecting the semiconductor die die5 located in the second signal channel B and in the Rank 1 region thereof to the third connection pad 106.

In some embodiments, still referring to FIG. 2, the fourth connection structures include a seventh sub-connection structure i and an eighth sub-connection structure j. The seventh sub-connection structure i is used for connecting the semiconductor die die3 located in the second signal channel B and in the Rank0 region thereof to the fourth connection pad 107; and the eighth sub-connection structure j is used for connecting the semiconductor die die7 located in the second signal channel B and in the Rank 1 region thereof to the fourth connection pad 107.

In some embodiments, still referring to FIG. 2, the plurality of semiconductor dies 103 stacked in sequence in the X-axis direction are stacked in the X-axis direction in a staggered manner; and two semiconductor dies adjacent in the X-axis direction are respectively located in the first signal channel A and the second signal channel B. For example, the two semiconductor dies adjacent in X-axis direction include die0 and die1, die1 and die4, die4 and die5, die5 and die2, die2 and die3, die3 and die6, and die6 and die7, in which, die0 and die1 are respectively located in the first signal channel A and the second signal channel B, and die1 and die4 are respectively located in the second signal channel B and the first signal channel A.

In some embodiments, still referring to FIG. 2, each two adjacent semiconductor dies located in the first signal channel A are separated by a semiconductor die located in the second signal channel B. For example, each two adjacent semiconductor dies located in the first signal channel A are die0 and die4, and die2 and die6 in sequence, in which die0 and die4 are separated by the semiconductor die die1 located in the second signal channel B, and die2 and die6 are separated by the semiconductor die die3 located in the second signal channel B.

In some embodiments, still referring to FIG. 2, each two adjacent semiconductor dies located in the second signal channel B are separated by a semiconductor die located in the first signal channel A. For example, each two adjacent semiconductor dies located in the second signal channel B are die1 and die5, and die3 and die7 in sequence, in which die1 and die5 are separated by the semiconductor die die4 located in the first signal channel A, and die3 and die7 are separated by the semiconductor die die6 located in the first signal channel A.

In some embodiments, still referring to FIG. 2, the two adjacent semiconductor dies die0 and die4 located in the first signal channel A and respectively located in the Rank0 region and Rank1 region thereof both receive a first signal, and the two adjacent semiconductor dies die1 and die5 located in the second signal channel B respectively located in the Rank0 region and Rank1 region thereof both receive a second signal, in which the first signal and the second signal may be low signals, for example, DQ0-7. The two adjacent semiconductor dies die2 and die6 located in the first signal channel A and respectively located in the Rank0 region and Rank1 region thereof both receive a third signal, and the two adjacent semiconductor dies die3 and die7 located in the second signal channel B and respectively located in the Rank0 region and Rank1 region thereof both receive a fourth signal, in which the third signal and fourth signal may be high signals, for example, DQ8-15. In the embodiments of the disclosure, the semiconductor dies receiving the low signals or the high signals are stacked together, which is beneficial to signal transmission and avoids crosstalk between the low signals and the high signals during signal transmission. In this way, the electrical performance of the semiconductor stack structure can be further improved.

In the embodiments of the disclosure, by adjusting the stack mode of the semiconductor dies, the length difference between the gold wires of the two ranks is reduced, thereby increasing the signal eye diagram and thus improving the performance of the packaging substrate.

In the embodiments of the disclosure, two semiconductor dies which are located in the different channel regions of a same signal channel and are connected with a same signal are arranged adjacently. For example, the semiconductor dies die0 and die4 respectively located in the first channel region and the second channel region of the first signal channel A and both connected to the first connection pad are arranged adjacently, the semiconductor dies die2 and die6 respectively located in the first channel region and the second channel region of the first signal channel A and both connected to the second connection pad are arranged adjacently, the semiconductor dies die1 and die5 respectively located in the first channel region and the second channel region of the second signal channel B and both connected to the third connection pad are arranged adjacently, and the semiconductor dies die3 and die7 respectively located in the first channel region and the second channel region of the second signal channel B and both connected to the fourth connection pad are arranged adjacently. In this way, the length difference between gold wires connected to such two semiconductor dies is reduced, thereby reducing the signal reflection, which can improve the performance of the semiconductor stack structure packaging substrate.

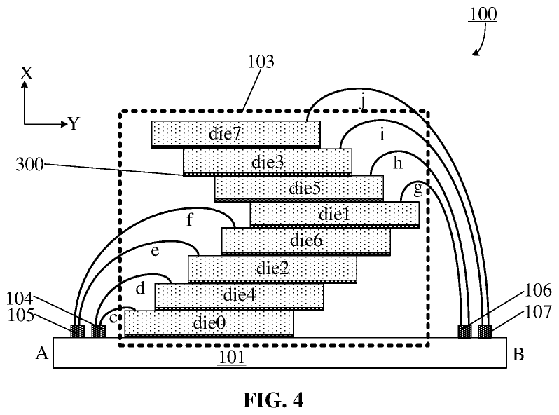

FIG. 4 is another schematic structural diagram of a semiconductor stack structure according to some embodiments of the present disclosure. As shown in FIG. 4, a semiconductor stack structure 100 includes: a substrate 101; connection pads located on a surface of the substrate 101; and a plurality of semiconductor dies 103 located on the surface of the substrate 101 and stacked in sequence in the X-axis direction. The plurality of semiconductor dies 103 include die0, die4, die2, die6, die1, die5, die3, and die7.

In some embodiments, still referring to FIG. 4, the connection pads include a first connection pad 104, a second connection pad 105, a third connection pad 106, and a fourth connection pad 107; and the signal channels include a first signal channel A and a second signal channel B. each two adjacent semiconductor dies in sequence located in the first signal channel A are respectively connected to the first connection pad 104 and the second connection pad 105; and each two adjacent semiconductor dies in sequence located in the second signal channel B are respectively connected to the third connection pad 106 and the fourth connection pad 107.

Still referring to FIG. 4, the semiconductor dies die0, die4, die2 and die6 are all located in the first signal channel A; and die1, die5, die3 and die7 are all located in the second signal channel B. Each two adjacent semiconductor dies located in the first signal channel A include die0 and die4, and die2 and die6, so that die0 and die4 are connected to the same connection pad 104, and die2 and die6 are connected to the same connection pad 105. Each two adjacent semiconductor dies located in the first signal channel B include die1 and die5, and die3 and die7, so that die1 and die5 are connected to the same connection pad 106, and die3 and die7 are connected to the same connection pad 107.

In the embodiments of the disclosure, the two semiconductor dies die0 and die4 connected to the same connection pad are located in a first channel region (i.e., a Rank0 region) and a second channel region (i.e., a Rank1 region) of the first signal channel A, respectively; the two semiconductor dies die2 and die6 connected to the same connection pad are located in the Rank0 region and the Rank1 region of the first signal channel A, respectively; the two semiconductor dies die1 and die5 connected to the same connection pad are located in a first channel region (i.e., another Rank0 region) and a second channel region (i.e., another Rank1 region) of the second signal channel B, respectively; and the two semiconductor dies die3 and die7 connected to the same connection pad are located in the Rank0 region and the Rank1 region of the second signal channel B, respectively.

In some embodiments, the semiconductor stack structure further includes connection structures. The connection structures include first connection structures, second connection structures, third connection structures and fourth connection structures. The first connection structures are used for connecting two adjacent semiconductor dies located in the first signal channel A to the first connection pad 104. The second connection structures are used for connecting another two adjacent semiconductor dies located in the first signal channel A to the second connection pad 105. The third connection structures are used for connecting two adjacent semiconductor dies located in the second signal channel B to the third connection pad 106. The fourth connection structures are used for connecting another two adjacent semiconductor dies located in the second signal channel B to the fourth connection pad 107.

In some embodiments, still referring to FIG. 4, the first connection structures include a first sub-connection structure c and a second sub-connection structure d. The first sub-connection structure c is used for connecting the semiconductor die die0 located in the first signal channel A and in the Rank0 region thereof to the first connection pad 104, and the second sub-connection structure d is used for connecting the semiconductor die die4 located in the first signal channel A and in the Rank 1 region thereof to the first connection pad 104. With the structure in FIG. 4, the length difference between the first sub-connection structure c and the second sub-connection structure d can be further reduced, thereby further reducing the influence of reflection on signal transmission, compared with the structure in FIG. 2.

In some embodiments, still referring to FIG. 4, the second connection structures include a third sub-connection structure e and a fourth sub-connection structure f. The third sub-connection structure e is used for connecting the semiconductor die die2 located in the first signal channel A and in the Rank0 region thereof to the second connection pad 105, and the fourth sub-connection structure f is used for connecting the semiconductor die die6 located in the first signal channel A and in the Rank 1 region thereof to the second connection pad 105.

In some embodiments, still referring to FIG. 4, the third connection structures include a fifth sub-connection structure g and a sixth sub-connection structure h. The fifth sub-connection structure g is used for connecting the semiconductor die die1 located in the second signal channel B and in the Rank0 region thereof to the third connection pad 106, and the sixth sub-connection structure h is used for connecting the semiconductor die die5 located in the second signal channel B and in the Rank 1 region thereof to the third connection pad 106.

In some embodiments, still referring to FIG. 4, the fourth connection structures include a seventh sub-connection structure i and an eighth sub-connection structure j. The seventh sub-connection structure i is used for connecting the semiconductor die die3 located in the second signal channel B and in the Rank0 region thereof to the fourth connection pad 107, and the eighth sub-connection structure j is used for connecting the semiconductor die die7 located in the second signal channel B and in the Rank 1 region thereof to the fourth connection pad 107.

In some embodiments, still referring to FIG. 4, the plurality of semiconductor dies 103 stacked in sequence in the X-axis direction are stacked in the X-axis direction in a cascade arrangement, and a first end or a second end of each of the plurality of semiconductor dies in a Y-axis direction is exposed.

In the embodiments of the disclosure, the two ends of each semiconductor die from left to right in the Y-axis direction are defined as the first end and the second end in sequence, and the plurality of semiconductor dies 103 stacked in sequence in the X-axis direction include die0, die4, die2, die6, die1, die5, die3 and die7. The first ends of the semiconductor dies die0, die4, die2 and die6 are all exposed, and the semiconductor dies with their first ends exposed are all located in the first signal channel A. The second ends of the semiconductor dies die1, die5, die3 and die7 are all exposed, and the semiconductor dies with their second ends exposed are all located in the second signal channel B.

In some embodiments, still referring to FIG. 4, the semiconductor dies located in the first signal channel A and connected to the first connection pad 104 or the second connection pad 105 are arranged adjacently. For example, the semiconductor dies die0 and die4 located in the first signal channel A and connected to the first connection pad 104 are arranged adjacently, and the semiconductor dies die2 and die6 located in the first signal channel A and connected to the second connection pad 105 are arranged adjacently.

In some embodiments, still referring to FIG. 4, the semiconductor dies located in the second signal channel B and connected to the third connection pad 106 or the fourth connection pad 107 are arranged adjacently. For example, the semiconductor dies die1 and die5 located in the second signal channel B and connected to the third connection pad 106 are arranged adjacently; and the semiconductor dies die3 and die7 located in the second signal channel B and connected to the fourth connection pad 107 are arranged adjacently.

In some embodiments, still referring to FIG. 4, the semiconductor stack structure 100 further includes an isolation attach film 300 located between two adjacent semiconductor dies. The isolation attach film 300 is located on a side of a semiconductor die close to the substrate 101 in the X-axis direction.

In the embodiments of the disclosure, two semiconductor dies which are located in the different channel regions of a same signal channel and are connected with a same signal are arranged adjacently. For example, the semiconductor dies die0 and die4 respectively located in the first channel region and the second channel region of the first signal channel A and both connected to the first connection pad are arranged adjacently, the semiconductor dies die2 and die6 respectively located in the first channel region and the second channel region of the first signal channel A and both connected to the second connection pad are arranged adjacently, the semiconductor dies die1 and die5 respectively located in the first channel region and the second channel region of the second signal channel B and both connected to the third connection pad are arranged adjacently, and the semiconductor dies die3 and die7 respectively located in the first channel region and the second channel region of the second signal channel B and both connected to the fourth connection pad are arranged adjacently. In this way, the length difference between gold wires connected to such two adjacent semiconductor dies can be reduced, thereby reducing the signal reflection, which can improve the performance of the semiconductor stack structure packaging substrate.

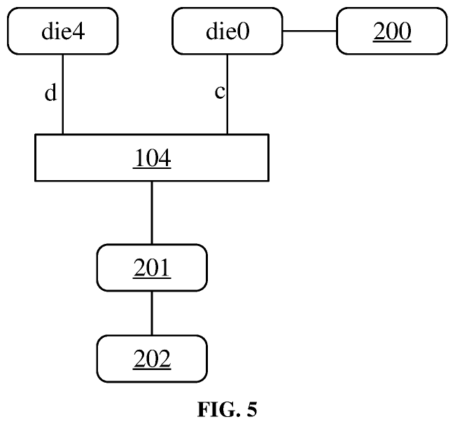

FIG. 5 is a schematic signal transmission diagram of dies connected to a same connection pad according to some embodiments of the present disclosure, and a phenomenon of reflection reduction in the signal transmission process in the dies will be explained below in conjunction with FIG. 5. As shown in FIG. 5, the semiconductor dies die0 and die4 are located in a Rank0 region and a Rank1 region of a first signal channel, respectively, and both die0 and die4 are connected to a connection pad 104. A first sub-connection structure c is a gold wire connecting die0 to the connection pad 104, and the length of the first sub-connection structure c is L1. A second sub-connection structure d is a gold wire connecting die4 and the connection pad 104, and the length of the second sub-connection structure d is L2. Die0 and die4 are arranged adjacently, so that the length L1 of the first sub-connection structure c is very close to the length L2 of the first sub-connection structure d. When the Rank0 is accessed, an On-Die Termination (ODT) 200 on die0 is turned on, which ODT can counteract most of the reflection of die0. At this time, since Rank1 is not accessed, the ODT on die4 is not turned on. As a result, the signal is reflected from die4 to the connection pad 104 and then reflected to Rank1, and the reflection of the Rank1 will return to the arterial road composed of a gold ball 201 and a controller 202, thus affecting the Rank0. However, in this case, since L1 and L2 are very close the reflection of Rank0 and the reflection of Rank1 converge at the connection pad 104 at the same time during signal transmission. Therefore, part of the reflection of Rank1 can be counteracted, so that the overall reflection is reduced, and thus the performance of the semiconductor stack structure packaging substrate is better.

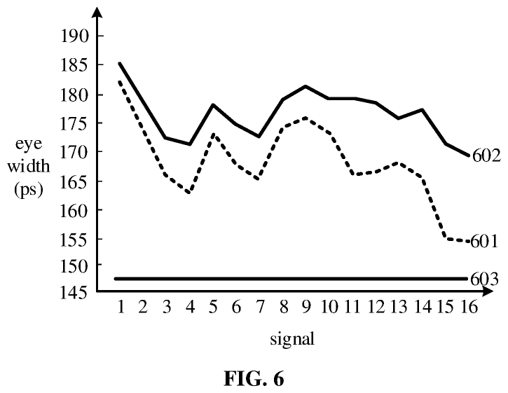

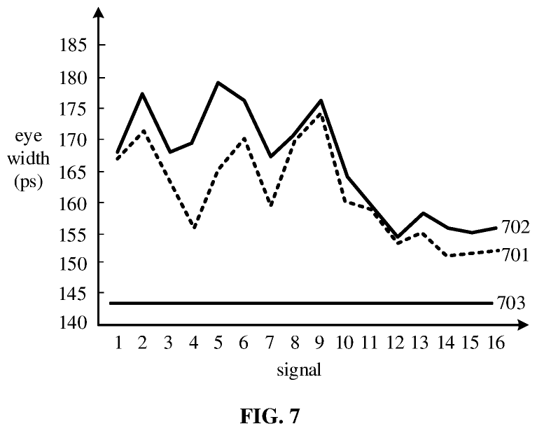

FIG. 6 is a curve of a signal eye diagram result during a writing process of a semiconductor stack structure according to some embodiments of the present disclosure. As shown in FIG. 6, during a writing process, an eye width curve 601 of a semiconductor stack structure in some implementations and an eye width curve 602 of a semiconductor stack structure in the embodiments of the disclosure are both higher than the lowest eye width curve 603 of a semiconductor stack structure during a writing process; and the eye width curve 601 during a writing process of the semiconductor stack structure in some implementations is significantly lower than the eye width curve 602 of the semiconductor stack structure in the embodiments of the disclosure at a same eye height. FIG. 7 is a curve of a signal eye diagram result during a reading process of a semiconductor stack structure according to some embodiments of the present disclosure. As shown in FIG. 7, during a reading process, an eye width curve 701 of a semiconductor stack structure in some implementations and an eye width curve 702 of a semiconductor stack structure in the embodiments of the disclosure are both higher than the lowest eye width curve 703 of a semiconductor stack structure during a reading process, and the eye width curve 701 of the semiconductor stack structure in some implementations is significantly lower than the eye width curve 702 of the semiconductor stack structure in the embodiments of the disclosure at a same eye height. Thus, the eye diagram performances (i.e., the eye width) of the semiconductor stack structure in the embodiments of the disclosure both during a reading process and a writing process is improved compared with that of the semiconductor stack structure in some implementations. Therefore, the eye diagram margin of the semiconductor stack structure in the embodiments of the disclosure is greater, and thus the performance of the packaging substrate is better.

In several embodiments provided by the disclosure, it should be understood that the disclosed structures may be implemented in a non-target way. The above-described structure embodiments are only illustrative. For example, the division of the units is only a logical function division, and there may be other division modes in actual implementation, for instance, multiple units or components may be combined or integrated into another system, or some features may be ignored or not executed. In addition, the components shown or discussed are coupled, or directly coupled to each other.

The features disclosed in several structure embodiments provided in the disclosure can be arbitrarily combined without conflict to obtain a new structure embodiment.

The above are only some implementations of the disclosure, but the protection scope of the disclosure is not limited to this. Any changes or replacements that can be easily thought of by a person skilled in the art within the technical scope disclosed by the disclosure shall be covered by the protection scope of the disclosure. Therefore, the protection scope of this disclosure shall be subject to the protection scope of the claims.

According to the semiconductor stack structure provided by the embodiments of the disclosure, each two adjacent semiconductor dies located in a same signal channel are connected to a same connection pad, and two semiconductor dies connected to a same connection pad are respectively located in a first channel region and a second channel region of a signal channel. That is, in the embodiments of the disclosure, two semiconductor dies which are located in the different channel regions of a same signal channel and are connected with a same signal are arranged adjacently, so that the length difference between gold wires connected to such two semiconductor dies is reduced, and further the signal reflection is reduced, thus improving the performance of a semiconductor stack structure packaging substrate.

What is claimed is:

1. A semiconductor stack structure, at least comprising:
a substrate;
connection pads located on a surface of the substrate; and
a plurality of semiconductor dies located on the surface of the substrate and stacked in sequence in a first direction, the first direction being a thickness direction of the substrate,
wherein each two adjacent semiconductor dies located in a same signal channel are connected to a same connection pad, and two semiconductor dies connected to a same connection pad are respectively located in a first channel region and a second channel region of a signal channel.

2. The semiconductor stack structure according to claim 1, wherein the semiconductor stack structure further comprises connection structures,
wherein the connection structures are used for connecting the semiconductor dies to the connection pads.

3. The semiconductor stack structure according to claim 2, wherein the semiconductor stack structure at least comprises a first connection pad and a second connection pad, and signal channels at least comprise a first signal channel,
wherein each two adjacent semiconductor dies in sequence located in the first signal channel are respectively connected to the first connection pad and the second connection pad.

4. The semiconductor stack structure according to claim 3, wherein the connection structures at least comprise first connection structures and second connection structures;
wherein the first connection structures are used for connecting two adjacent semiconductor dies located in the first signal channel to the first connection pad; and
the second connection structures are used for connecting another two adjacent semiconductor dies located in the first signal channel to the second connection pad.

5. The semiconductor stack structure according to claim 4, wherein the first connection structures comprise a first sub-connection structure and a second sub-connection structure,
wherein the first sub-connection structure is used for connecting a semiconductor die located in the first channel region in the first signal channel to the first connection pad; and
the second sub-connection structure is used for connecting a semiconductor die located in the second channel region in the first signal channel to the first connection pad.

6. The semiconductor stack structure according to claim 4, wherein the second connection structures comprise a third sub-connection structure and a fourth sub-connection structure,
wherein the third sub-connection structure is used for connecting another semiconductor die located in the first channel region in the first signal channel to the second connection pad; and
the fourth sub-connection structure is used for connecting another semiconductor die located in the second channel region in the first signal channel to the second connection pad.

7. The semiconductor stack structure according to claim 3, wherein the semiconductor stack structure further comprises a third connection pad and a fourth connection pad, and the signal channels further comprise a second signal channel,
wherein each two adjacent semiconductor dies in sequence located in the second signal channel are respectively connected to the third connection pad and the fourth connection pad.

8. The semiconductor stack structure according to claim 7, wherein the connection structures further comprise third connection structures and fourth connection structures,
the third connection structures are used for connecting two adjacent semiconductor dies in the second signal channel to the third connection pad; and
the fourth connection structures are used for connecting another two adjacent semiconductor dies in the second signal channel to the fourth connection pad.

9. The semiconductor stack structure according to claim 8, wherein the third connection structures comprise a fifth sub-connection structure and a sixth sub-connection structure,
wherein the fifth sub-connection structure is used for connecting a semiconductor die located in the first channel region in the second signal channel to the third connection pad; and
the sixth sub-connection structure is used for connecting a semiconductor die located in the second channel region in the second signal channel to the third connection pad.

10. The semiconductor stack structure according to claim 8, wherein the fourth connection structures comprise a seventh sub-connection structure and an eighth sub-connection structure,
wherein the seventh sub-connection structure is used for connecting another semiconductor die located in the first channel region in the second signal channel to the fourth connection pad; and
the eighth sub-connection structure is used for connecting another semiconductor die located in the second channel region in the second signal channel to the fourth connection pad.

11. The semiconductor stack structure according to claim 8, wherein the plurality of the semiconductor dies are stacked in the first direction in a staggered manner; and
two semiconductor dies adjacent in the first direction are respectively located in the first signal channel and the second signal channel.

12. The semiconductor stack structure according to claim 11, wherein each two adjacent semiconductor dies located in the first signal channel are separated by a semiconductor die located in the second signal channel; and
each two adjacent semiconductor dies located in the second signal channel are separated by a semiconductor die located in the first signal channel.

13. The semiconductor stack structure according to claim 8, wherein the plurality of semiconductor dies are stacked in the first direction in a cascade arrangement, and a first end or a second end of each of the semiconductor chips in a second direction is exposed; the second direction being parallel to a plane where the substrate is located,
wherein the semiconductor dies with first ends exposed is located in the first signal channel; and
the semiconductor dies with second ends exposed is located in the second signal channel.

14. The semiconductor stack structure according to claim 13, wherein the semiconductor dies located in the first signal channel and connected to the first connection pad or the second connection pad are arranged adjacently; and
the semiconductor dies located in the second signal channel and connected to the third connection pad or the fourth connection pad are arranged adjacently.

15. The semiconductor stack structure according to claim 1, wherein the semiconductor stack structure further comprises an isolation attach film located between two adjacent semiconductor dies,
wherein the isolation attach film is located on a side of a semiconductor die close to the substrate in the first direction.
